(19) United States
(12) Patent Application Publication
(10) Pub. No.: US 2008/0156973 A1
(43) Pub. Date: Jul. 3, 2008

(54) PHOTOSENSOR ARRAY FOR OPTICAL ENCODER

(76) Inventors: Weng Fei Wong, Penang (MY); Chee Foo Lum, Penang (MY); Siang Leong Foo, Penang (MY)

Correspondence Address: Kathy Manke;Avago Technologies Limited, 4380 Ziegler Road, Fort Collins, CO, 80525, US

(21) Appl. No.: 11/618,691

(22) Filed: Dec. 29, 2006

(51) Int. Cl. G01D 5/34; H01L 27/00

(52) U.S. Cl. 250/231.16; 250/231.13; 250/208.1

(57) ABSTRACT

An optical encoder. A reflective optical encoder includes a reflective coding element, a plurality of emitters, and a detector. The reflective coding element includes a track of alternating reflective and non-reflective sections. Each of the plurality of emitters is configured to generate corresponding light signals incident on the track of the coding element. The detector is configured to detect the corresponding light signals reflected off of the reflective sections of the track. In one embodiment, the detector includes a plurality of photosensors positioned in separate photosensor groupings, and each photosensor grouping corresponds to one of the plurality of emitters. Embodiments of the optical encoder are suitable for small form factor encoders and improve the ease encoder assembly.

### BACKGROUND OF THE INVENTION

Optical encoders are used to monitor the motion of, for example, a shaft such as a crank shaft. Optical encoders can monitor the motion of a shaft in terms of position and/or number of revolutions of the shaft. Optical encoders are employed in systems to provide high resolution within tight size limitations.

Optical encoders typically use a code wheel attached to the shaft to modulate light as the shaft and the code wheel rotate. In a transmissive code wheel, the light is modulated as it passes through transmissive sections of a track on the code wheel. The transmissive sections are separated by non-transmissive sections. In a reflective code wheel, the light is modulated as it is reflected off of reflective sections of the track on the code wheel. The reflective sections are separated by non-reflective sections. As the light is modulated in response to the rotation of the code wheel, a stream of electrical signals is generated from a photosensor array, which receives the modulated light. The electrical signals are used to determine the position and/or number of revolutions of the shaft.

FIG. 1a illustrates a conventional transmissive optical encoder system 10. The optical encoder system 10 includes an encoder 12 and a transmissive code wheel 14. The encoder 12 includes an emitter 16 and a detector 18. The emitter 16 emits light, which passes through the transmissive sections of the code wheel 14 and is detected by the detector 18. Given that the transmissive optical encoder system 10 implements the emitter 16 on one side of the code wheel 14 and the detector 18 on the other side of the code wheel 14, the transmissive optical encoder system 10 consumes a substantial amount of space.

Optical encoders that are used to determine absolute position typically have a code wheel with a separate track for each bit of resolution that is desired. For example, an encoder with 4-bit resolution typically implements four different tracks, with each track having a corresponding photosensor. The tracks are separated from each other by enough distance that light from the different tracks does not mix at the photosensors. The photosensors are aligned with the separate tracks.

FIG. 1b illustrates a conventional multi-bit detector 18. The conventional multi-bit detector 18 includes a linear array of photosensors 20. The photosensors 20 are arranged in a straight line near the centerline of the array. The detector 18 also includes a monitor photosensor 22 to generate and index signal. The monitor photosensor 22 is aligned with the other photosensors 20 of the array.

### SUMMARY OF THE INVENTION

Embodiments of an optical encoder are described. One embodiment of a reflective optical encoder includes a reflective coding element, a plurality of emitters, and a detector. The reflective coding element includes a track of alternating reflective and non-reflective sections. Each of the plurality of emitters is configured to generate corresponding light signals incident on the track of the coding element. The detector is configured to detect the corresponding light signals reflected off of the reflective sections of the track. In one embodiment, the detector includes a plurality of photosensors positioned in separate photosensor groupings, and each photosensor grouping corresponds to one of the plurality of emitters.

In some embodiments of the optical encoder, the photosensors are positioned near edges of the detector. Some embodiments include an encapsulant to encapsulate the plurality of emitters and the plurality of photosensors. The encapsulant may form a plurality of lenses, each lens aligned with one of the photosensor groupings and a corresponding emitter. Additionally, each lens may be configured to direct the light signal from the corresponding emitter to the track, and to direct the reflected light signal from the track to the corresponding photosensor grouping. The coding element may be a code wheel or a code strip.

In another embodiment, the optical encoder includes means for generating multiple light signals incident on a track of a coding element, means for detecting motion of the coding element, and means for reducing cross-talk of the multiple light signals. Other embodiments of the optical encoder are also described.

One embodiment of a detector within an optical encoder includes a first photosensor grouping and a second photosensor grouping. The first photosensor grouping is positioned near a first edge of the detector and includes at least one photosensor. The second photosensor grouping is positioned at an opposite edge of the detector and includes at least one photosensor. Other embodiments of the detector are also described.

Other aspects and advantages of embodiments of the present invention will become apparent from the following detailed description, taken in conjunction with the accompanying drawings, illustrated by way of example of the principles of the invention.

### BRIEF DESCRIPTION OF THE DRAWINGS

FIG. 1A depicts a conventional transmissive optical encoder system.

FIG. 1B depicts a conventional multi-bit detector.

FIG. 2 depicts a schematic circuit diagram of one embodiment of a reflective optical encoding system.

FIG. 3 depicts a schematic diagram of one embodiment of a reflective absolute code wheel.

FIGS. 4A, 4B, and 4C depict schematic diagrams of alternative embodiments of a reflective code wheel.

FIG. 5A depicts one embodiment of a layout of an encoder on a circuit substrate.

FIG. 5B depicts another embodiment of a layout of an encoder on a circuit substrate with independent lenses for the emitters and photodiodes.

FIG. 6 depicts a sectional view of the encoder of FIG. 5A.

FIG. 7 depicts a side view of the encoder and encapsulant of FIG. 6.

FIGS. 8A and 8B depict different perspective views of a schematic diagram of one embodiment of an encoder package.

FIG. 9 depicts a schematic diagram of one embodiment of an imaging encoding system.

FIG. 10 depicts a schematic diagram of one embodiment of an absolute code strip.

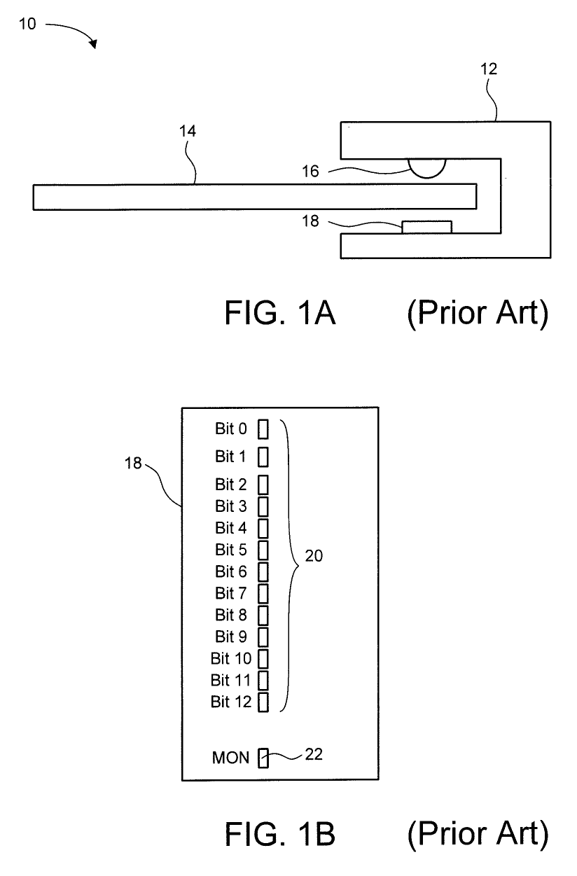

Throughout the description, similar reference numbers may be used to identify similar elements.

### DETAILED DESCRIPTION

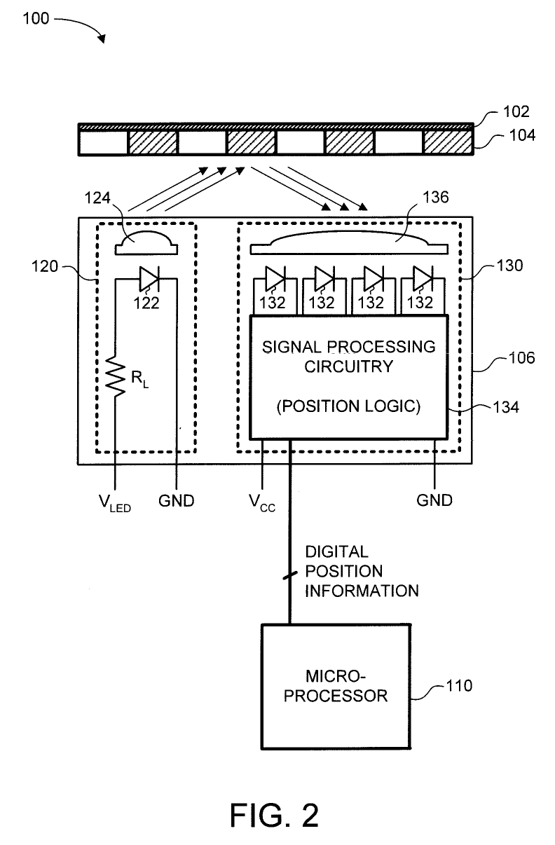

FIG. 2 depicts a schematic circuit diagram of one embodiment of a reflective optical encoding system 100. The illustrated reflective optical encoding system 100 includes a reflective material 102, a code wheel 104, an encoder 106, and a microprocessor 110. In one embodiment, the reflective material 102 is a coating or a substrate that is physically coupled to the code wheel 104. In some embodiments, the reflective surface of the reflective material 102 is coupled to the code wheel 104 opposite the encoder 106.

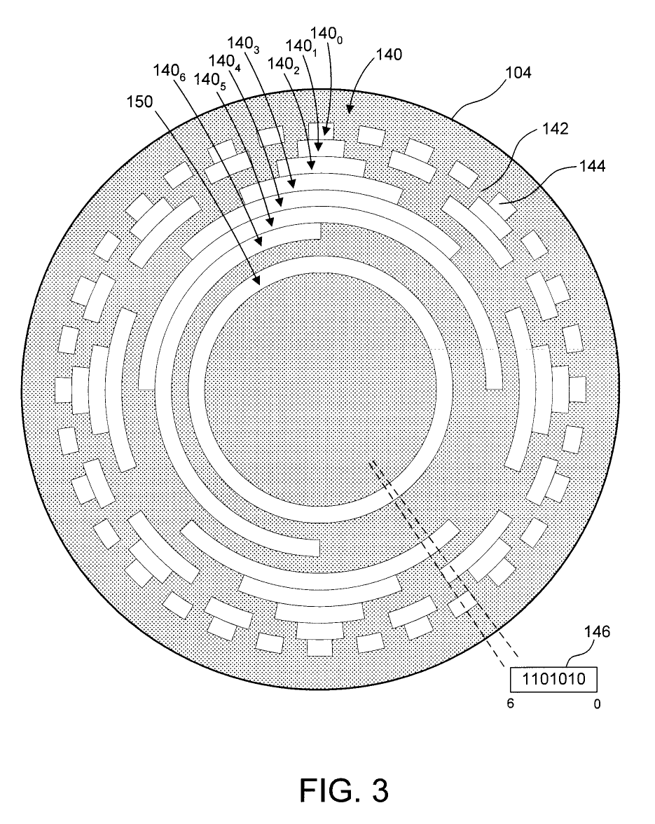

Although a more detailed illustration of the code wheel 104 is provided in FIG. 3, a brief explanation is provided here as context for the operation of the reflective optical encoding system 100 shown in FIG. 2. In general, the code wheel 104 includes one or more tracks 140 of reflective sections 142 and non-reflective sections 144. An emitter 120 in the encoder 106 produces light that is incident on the code wheel tracks 140. As the code wheel 104 is rotated, for example by a motor shaft (not shown), the incident light is reflected by the reflective sections 142 of the tracks 140, but is not reflected by the non-reflective sections 144 of the tracks 140. Thus, the light is reflected by the tracks 140 in a modulated pattern (i.e., on-off-on-off . . . ). A detector 130 in the encoder 106 detects the modulated, reflected light signal and, in response, generates one or more corresponding signals. In some embodiments, the detector 130 also may generate a monitor signal or an indexing signal. These signals are then transmitted to the microprocessor 110. The microprocessor 110 uses the signals to evaluate the movement of, for example, the motor shaft or other moving part to which the code wheel 104 is coupled.

In one embodiment, the encoder 106 includes the emitter 120 and the detector 130. The emitter 120 includes a light source 122 such as a light-emitting diode (LED). For convenience, the light source 122 is described herein as an LED, although other light sources, or multiple light sources, may be implemented. In one embodiment, the LED 122 is driven by a driver signal, V_{LED}, through a current-limiting resistor, R_{L}. The details of such driver circuits are well-known. Some embodiments of the emitter 120 also may include a lens 124 aligned with the LED 122 to direct the projected light in a particular path or pattern. For example, the lens 124 may focus the light onto one or more of the code wheel tracks 140.

In one embodiment, the detector 130 includes one or more photosensors 132 such as photodiodes. The photosensors may be implemented, for example, in an integrated circuit (IC). For convenience, the photosensors 132 are described herein as photodiodes, although other types of photosensors may be implemented. In one embodiment, the photodiodes 132 are uniquely configured to detect a specific pattern or wavelength of reflected light. In some embodiments, several photodiodes 132 may be used to detect modulated, reflected light signals from multiple tracks 140, including position tracks and index tracks. Also, the photodiodes 132 may be arranged in a pattern that corresponds to the radius and design of the code wheel 104. The various patterns of photodiodes 132 are referred to herein as photosensor arrays. The signals produced by the photodiodes 132 are processed by signal processing circuitry 134 which generates the digital position information. In one embodiment, the signal processing circuitry includes position logic to generate the digital position information according to the detected light from the multiple tracks 140.

In one embodiment, the detector 130 also includes one or more comparators (not shown) to generate the digital position information. For example, analog signals from the photodiodes 132 may be converted by the comparators to transistor-transistor logic (TTL) compatible, digital output signals. In one embodiment, these output signals indicate position and direction information for the modulated, reflected light signal. Additionally, the detector 130 may include a lens 136 to direct the reflected light signal toward the photodiodes 132.

In some embodiments, the emitter 120 and one or more photodiodes 132 may be positioned together in a group, and a single lens 136 may be used for the emitter 120 and the photodiodes 132. Additionally, some embodiments may implement several groups of emitters 120 and photodiodes 132, with or without corresponding lenses 136.

In one embodiment, the reflective optical encoding system 100 includes components for determining absolute position. For example, the encoder 106 may include additional tracks 140, photodiodes 132, LEDs 122, or other components to allow the encoder 106 to determine an absolute angular position of the code wheel 104 upon power up. The absolute angular position can be determined using many known techniques. One exemplary technique, with corresponding hardware, is described in more detail in U.S. patent Ser. No. 11/445,661, filed on Jun. 2, 2006, entitled “Multi-bit absolute position optical encoder with reduced number of tracks,” which is incorporated by reference herein. Another exemplary absolute encoder is described in more detail in U.S. Pat. No. 7,112,781, entitled “Absolute encoder,” which is incorporated by reference herein. Additional details of emitters, detectors, and optical encoders, generally, may be referenced in U.S. Pat. Nos. 4,451,731, 4,691,101, and 5,241,172, which are incorporated by reference herein.

FIG. 3 depicts a schematic diagram of one embodiment of an absolute code wheel 104. In particular, FIG. 3 illustrates a top view of a circular absolute code wheel 104 in the shape of a disc. In some embodiments, the code wheel 104 may be in the shape of a ring, rather than a disc. The illustrated code wheel 104 includes multiple tracks 140, which may be circular tracks that are concentric with the code wheel 104. For example, the depicted code wheel 104 includes seven different tracks designated track 140₀ (the outermost track), track 140₁, track 140₂, track 140₃, track 140₄, track 140₅, track 140₆ (the innermost track).

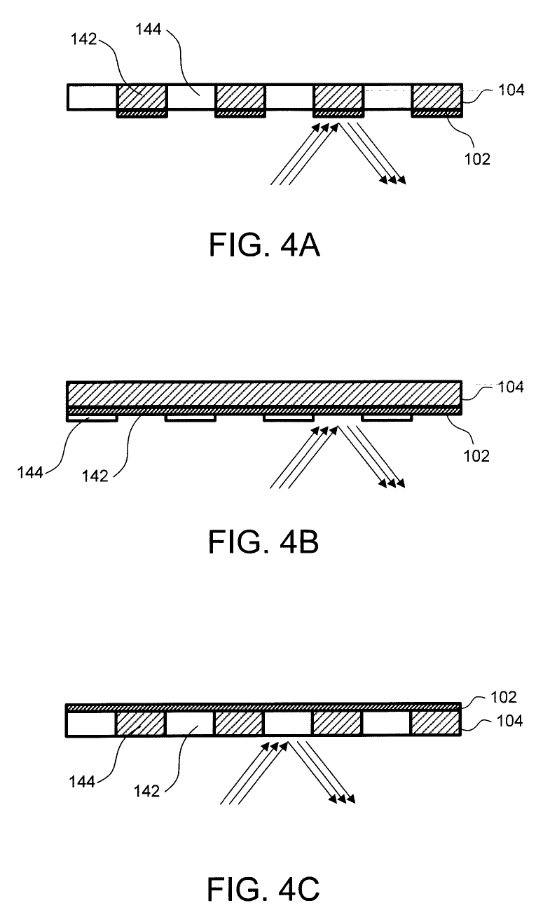

In one embodiment, the each track 140 includes a continuous repeating pattern that goes all the way around the code wheel 104. The depicted pattern of each track 140 includes alternating reflective sections 142 and non-reflective sections 144, although other patterns may be implemented. These reflective sections 142 and non-reflective sections 144 are also referred to as position sections. In one embodiment, the reflective sections 142 of the code wheel 104 are reflective spokes of the code wheel 104, and the non-reflective sections 144 are transparent windows or voids (without a reflective coating 102 on the opposite side of the windows or voids). In this embodiment, the entire code wheel 104 may have a reflective material 102 applied to the near surface. This embodiment is illustrated in FIG. 4A.

In another embodiment, the underside of the code wheel 104 may be coated with reflective material 102 such as bright nickel (Ni) or chrome, and a non-reflective track pattern can be applied to the reflective material 102. The non-reflective pattern may be silk-screened, stamped, ink jet printed, or otherwise applied directly onto the reflective surface on the code wheel 104. Alternatively, the non-reflective pattern may be formed as a separate part such as by injection molding, die-cutting, punching (e.g., film), or otherwise forming a non-reflective component which has opaque spokes on it. This embodiment is illustrated in FIG. 4B.

In another embodiment, the reflective sections 142 are transparent sections of the code wheel 104 with a reflective coating 102 on the opposite side of the code wheel 104. In this embodiment, the non-reflective sections 144 may be opaque so that they absorb the light from the LED 122. This embodiment is illustrated in FIG. 4C.

Also, it should be noted that, in some embodiments, the circular code wheel 104 could be replaced with a coding element that is not circular. For example, a linear coding element such as a code strip may be used. In another embodiment, a circular coding element may be implemented with a spiral bar pattern, as described in U.S. Pat. No. 5,017,776, which is incorporated by reference herein. Alternatively, other light modulation patterns may be implemented on various shapes of coding elements.

As described above, rotation of the code wheel 104 and, hence, the track 140 results in modulation of the reflected light signal at the detector 130 to generate absolute positional signals corresponding to the angular position of the code wheel 104. For this reason, the tracks 140 may be referred to as position tracks. Other embodiments of the code wheel 104 may include other tracks such as additional position tracks, as are known in the art.

In one embodiment, each radial combination of position tracks 140 (e.g., taken along a radius of the code wheel 104) corresponds to a unique digital position output 146. For example, the indicated radial combination (between the dashed radial lines) of position tracks 140 corresponds to a digital position output 146 of 1101010. In one embodiment, each bit of the digital position output 146 corresponds to one of the position tracks 140. As one example, the least significant bit (LSB) corresponds to the first position track 140₀, and the most significant bit (MSB) corresponds to the last position track 140₆. Alternatively, other bit ordering may be implemented. Also, a convention may be used to designate digital high and low signals, e.g., non-reflective sections 144 correspond to a digital low signal, “0,” and reflective sections 142 correspond to a digital high signal, “1.” Alternatively, other digital conventions may be used.

In the depicted embodiment, the position track sections 142 and 144 within each track 140 have the same circumferential dimensions (also referred to as the width dimension). In other words, the intermediate non-reflective track sections 144 in the first (outermost) position track 140₀ have the same width dimension as the reflective track sections 142 in the first position track 140₀. Similarly, the reflective and non-reflective track sections 142 and 144 in the second position track 140₁ have equal width dimensions (which, in this depicted embodiment are twice the width of the track sections 142 and 144 of the first position track in position track 140₀). The resolution of each position track 140 of the code wheel 104 is a function of the width dimensions of the positional track sections 142 and 144. In one embodiment, the width dimensions of the non-reflective track sections 144 are a function of the amount of area required to produce a detectable gap between consecutive, reflected light pulses. The position tracks 140 also have a radial, or height, dimension.

In addition to the illustrated position track 140 and position sections 142 and 144, the code wheel 104 also may include an index track or a monitor track 150. Since index tracks and monitor tracks are well known, additional details are not provided.

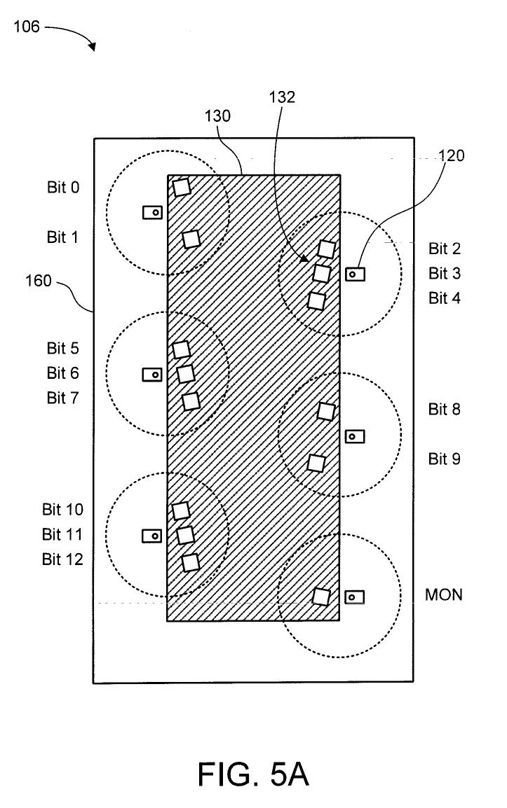

FIG. 5A depicts one embodiment of a layout of an encoder 106 on a circuit substrate 160. In particular, FIG. 5A shows an embodiment of a 13-bit reflective encoder 106 because the detector 130 includes thirteen photodiodes 132 (although other encoders 106 and detectors 130 may have fewer or more bits). In one embodiment, the circuit substrate 160 is used to mount the encoder 106, including the emitters 120 and the detector 130. Some exemplary types of circuit substrates 160 include, but are not limited to, printed circuit board (PCB), flexible circuit, leadframe, insert molded leadframe, glass substrate, ceramic substrate, molded interconnect device (MID), and so forth. Alternatively, other types of circuit substrates 160 may be implemented. In some embodiments, other circuitry also may be mounted on the circuit substrate 160. However, in some embodiments, the amount of circuitry mounted to the circuit substrate 160 may be limited to keep the thickness of the optical encoder 106 small.

The photodiodes 132 are arranged in multiple groupings, as indicated by the dashed circles. More generally, the groupings are also referred to as photodiode, or photosensor, groupings. Each grouping includes at least one photodiode 132 and a corresponding emitter 120. In one embodiment, the number of photodiodes 132 corresponds to the number of tracks 140 and 150 on the code wheel 104. The number of photodiodes 132 also may determine the number of bits output by the encoder 106. In one embodiment, one grouping may include an emitter 120 and a single photodiode 132 for use as a monitor photodiode aligned with the index track 150.

In one embodiment, the photodiodes 132 are arranged so that light is incident on and reflected from the code wheel 104 approximately at a centerline between the LED 122 of the emitter 120 and the photodiodes 132 of the detector 130. Various methods may be used to implement the emitter 120 and detector 130. In one embodiment, the emitter 120 and detector 130 may be implemented using chip-on-board technology. Alternatively, the emitter 120 and detector 130 may be implemented as a discrete transfer molded emitter-detector package. In one embodiment, the emitter 120 and decoder 130 may be attached as bare dice onto the circuit substrate 160 to achieve a particular thickness of the optical encoder 106. In this way, the emitter 120 and detector 130 may be die-attached close together to reduce or minimize the potential loss of light power. Additionally, the mounting of the emitter 120 and detector 130 may enable a small gap between the encoder 106 and the code wheel 104. The gap between the encoder 106 and the code wheel 104 also may depend on the use of an encapsulant, if any, to encapsulate part or all of the encoder 106.

In some embodiments, the photodiodes 132 are positioned at approximately the edges of the detector 130. For example, the illustrated encoder 106 includes eight photodiodes 132 positioned in three groupings at a first edge of the detector 130, and six photodiodes 132 positioned in three groupings at the opposite edge of the detector 130. In some embodiments, grouping the photodiodes 132 with separate emitters 120 helps to reduce cross-talk due to multiple light sources. The use of optical lenses, as described below, also may reduce such cross-talk.

Additionally, the photodiodes 132 of each grouping may be positioned along radial lines of the code wheel 104 so that when the encoder 106 is assembled with the code wheel 104, the photodiodes 132 in a single grouping follow the radius of the code wheel 104. For example, a first grouping of photodiodes 132 may be positioned along a first radial line of the code wheel 104, and a second grouping of photodiodes 132 may be positioned along a second radial line of the code wheel 104. The first grouping may be positioned at a first non-zero angle with respect to the first edge of the detector 130, and the second grouping may be positioned at a second non-zero angle with respect to the opposite edge of the detector 130. In this way, each grouping of photodiodes 132 may be positioned at a unique angle depending on the radial lines of the code wheel 104 when the encoder 106 is assembled with the code wheel 104.

It should be noted that the geometrical dimensions of the photodiodes 132 may be referenced to the corresponding optical sizes of the track sections 142 and 144 of the track 140. For example, optical magnification may be used to optically match the sizes of the photodiodes 132 and the track sections 142 and 144. In one embodiment, the optical magnification is approximately 2× so that a geometrically smaller code wheel 104 is optically matched to a larger array of photodiodes 132. This optical magnification may be achieved by using optical lenses, as described below.

Also, it should be noted that multiple photodiodes 132 may be used per track 140. In one embodiment, the signals from each set of photodiodes 132 for a single track 140 may be averaged together or otherwise combined to result in a single output signal for each of the corresponding sets of photodiodes 132.

FIG. 5B depicts another embodiment of a layout of an encoder 106′ on a circuit substrate 160 with independent lenses for the emitters 120 and photodiodes 132. Although embodiments of the optical lenses are described in more detail, FIG. 5B shows dashed circles to indicate that multiple optical lenses can be implemented for each grouping of photodiodes 132. In alternative embodiments, the photodiodes 132 may be grouped in other groupings with the optical lenses (e.g., one lens per photodiode 132), or the encoder 106′ may be implemented without any lenses.

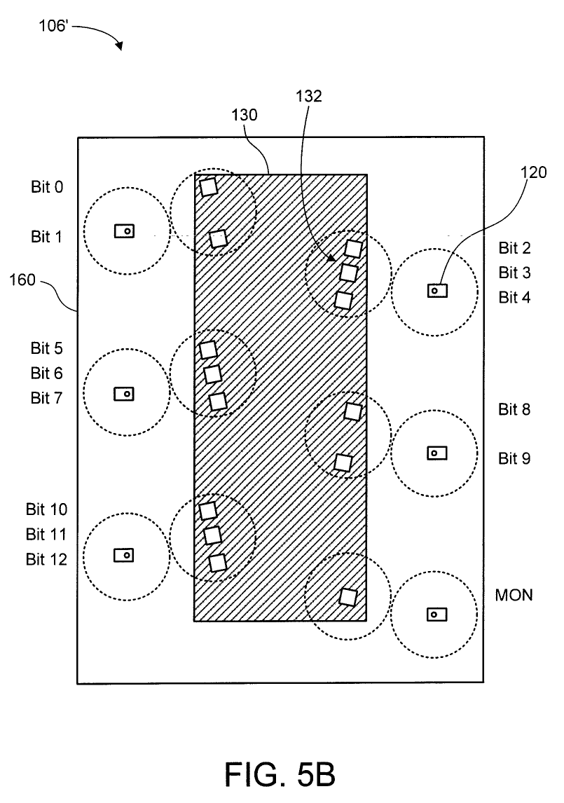

FIG. 6 depicts a sectional view of the encoder 106 of FIG. 5A. In addition to the components described above (shown dashed), FIG. 6 also illustrates an encapsulant 162 which encapsulates the emitters 120 and the detector 130, including the photodiodes 132. One example of the encapsulant 162 is an epoxy, although other types of encapsulants may be used. Thus, the encapsulant 162 may be used to package the encoder 106.

In some embodiments, the encapsulant 162 may form one or more optical lenses 162. The optical lenses 162 may be aligned with the individual groupings of photodiodes 132. Aligning the emitters 120, photodiodes 132, and lenses 162 in this manner allows the lenses 162 to direct light from the corresponding emitter 120 to the code wheel 104, and from code wheel 104 to the corresponding photodiodes 132. In another embodiment, the lenses 162 may be formed separately from the encapsulant 162.

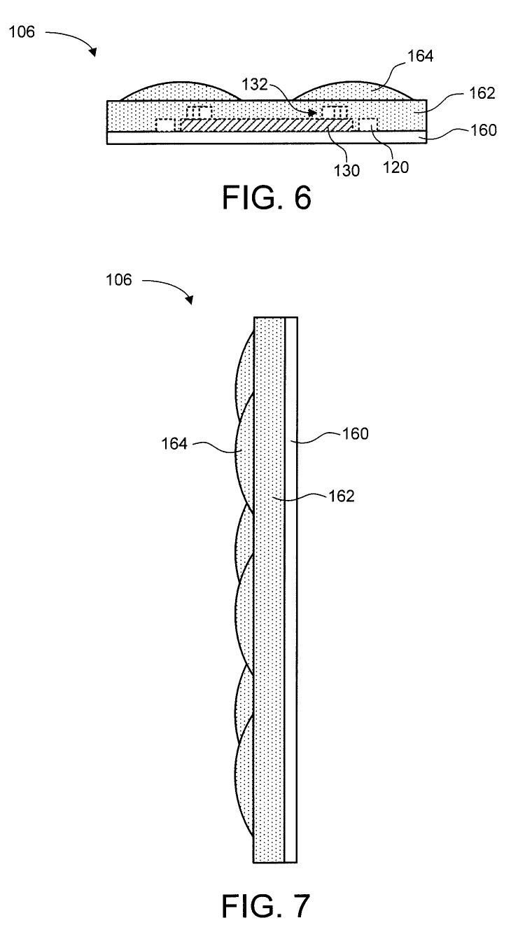

FIG. 7 depicts a side view of the encoder 106 and encapsulant 162 of FIG. 6. Although the internal components of the encoder 106 are not shown, FIG. 7 illustrates how the lenses 164 formed by the encapsulant 162 may be staggered, or arranged in another pattern, to correspond to the locations of the emitters 120 and groupings of photodiodes 132.

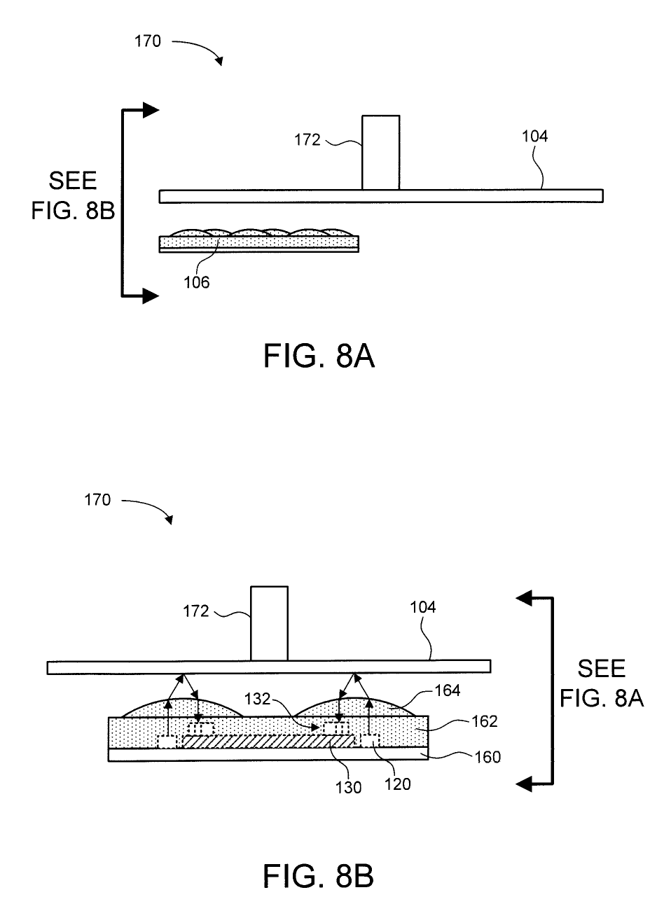

FIGS. 8A and 8B depict different perspective views of a schematic diagram of one embodiment of an encoder package 170. In particular, FIG. 8A depicts a side view of the encoder package 170, and FIG. 8B depicts an end view of the encoder package 170. Embodiments of the encoder package 170 include a code wheel 104 coupled to a motor shaft 172, so that the code wheel 104 rotates with the motor shaft 172. The emitter 120 and detector 130 are disposed on the substrate 160 on the same side of the code wheel 104. In one embodiment, the emitter 120 and detector 130 are encapsulated together by the encapsulant 162, which forms convex lenses 164 above the dice. FIG. 8B also shows how the lenses 162 direct light from the emitters 120 to the code wheel 104, and from the code wheel 104 to the corresponding photodiodes 132. Other types of encoders also may be implemented.

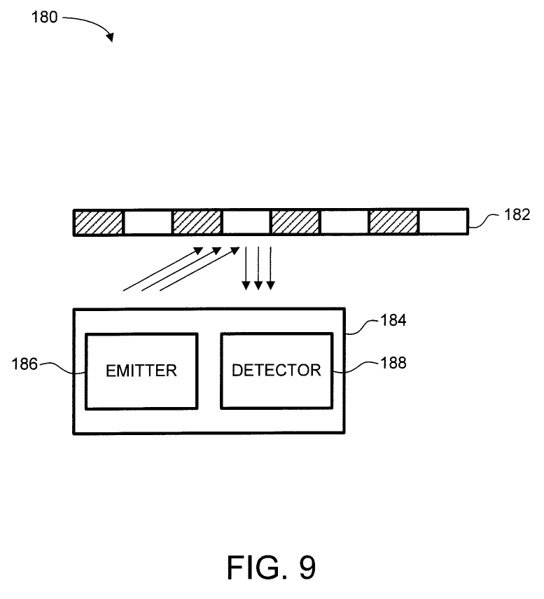

FIG. 9 depicts a schematic diagram of one embodiment of an imaging encoding system 180. The illustrated imaging encoding system 180 includes an imaging coding element 182, for example, an imaging code wheel or strip. The functionality of the imaging code wheel 182 is substantially similar to the functionality of the reflective code wheel 104, described above, except that the imaging code wheel 182 does not necessarily have a reflective material 102 applied to the opposite side of the code wheel 182.

In some aspects, the imaging encoder 184 operates similarly to the encoder 106 described above. The imaging encoder 184 includes an emitter 186 and a detector 188. However, in contrast to the reflective optical encoding system 100 of FIG. 2, the imaging encoding system 180 differentiates between different track sections on the imaging code wheel 182 based on how the light bounces back from the non-absorptive pattern on the code wheel 182. In particular, the detector 188 detects the diffuse portion of the light, rather than a reflective portion. Additional details of at least one embodiment of an imaging encoding system 180 are described in U.S. Pat. No. 7,102,123, which is incorporated by reference herein.

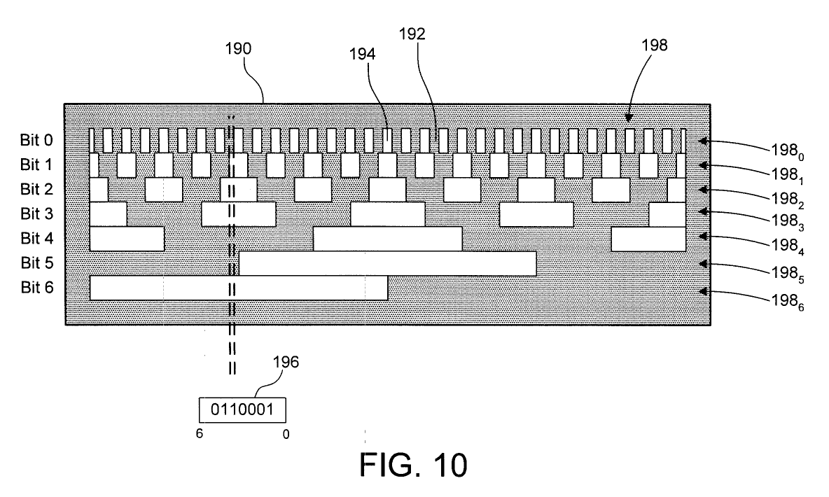

FIG. 10 depicts a schematic diagram of one embodiment of an absolute code strip 190. The functionality of the code strip 190 is substantially similar to the functionality of the code wheel 104 described above, except that the code strip 190 may be used to monitor and limit movement in a substantially linear direction. The illustrated code strip 190 includes seven linear position tracks 198. Each position track 198 includes reflective sections 192 and non-reflective sections 194, which are position sections. In one embodiment, the position track sections 192 and 194 within each position track 198 have approximately the same width dimension. Similarly, the position track sections 192 and 194 have approximately the same height dimension. In another embodiment, the position track sections 192 and 194 may be imaging sections, rather than reflective and non-reflective sections. Additionally, other embodiments of the code strip 190 may include multiple position tracks or index tracks.

In one embodiment, each vertical combination of position tracks 198 corresponds to a unique digital position output 196. For example, the indicated vertical combination (between the dashed vertical lines) of position tracks 198 corresponds to a digital position output 196 of 0101110. In one embodiment, each bit of the digital position output 196 corresponds to one of the position tracks 198. As one example, the least significant bit (LSB) corresponds to the first position track 198₀, and the most significant bit (MSB) corresponds to the last position track 198₆. Alternatively, other bit ordering and/or digital conventions may be implemented.

Embodiments of the optical encoder 106 described above are suitable for small form factor encoders. This allows the optical encoder 106 to be used in applications with limited space such as in a sensor in a slim chip feeder for a surface mount machine. Additionally, embodiments of the optical encoder 106 improve the ease encoder assembly.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A reflective optical encoder comprising:
a reflective coding element comprising a track of alternating reflective and non-reflective sections;
a plurality of emitters configured to generate corresponding light signals incident on the track of the coding element; and
a detector configured to detect the corresponding light signals reflected off of the reflective sections of the track, wherein the detector comprises a plurality of photosensors positioned in separate photosensor groupings, each photosensor grouping corresponding to one of the plurality of emitters.

2. The reflective optical encoder of claim 1 wherein the plurality of photosensors are positioned near edges of the detector.

3. The reflective optical encoder of claim 1 further comprising an encapsulant to encapsulate the plurality of emitters and the plurality of photosensors.

4. The reflective optical encoder of claim 3 wherein the encapsulant forms a plurality of lenses, each lens aligned with one of the photosensor groupings and a corresponding emitter.

5. The reflective optical encoder of claim 4 wherein each lens is configured to direct the light signal from the corresponding emitter to the track, and to direct the reflected light signal from the track to the corresponding photosensor grouping.

6. The reflective optical encoder of claim 1 wherein the coding element comprises a code wheel.

7. The reflective optical encoder of claim 1 wherein the coding element comprises a code strip.

8. The reflective optical encoder of claim 1 wherein at least one of the separate photosensor groupings comprises a single photosensor.

9. The reflective optical encoder of claim 8 wherein the single photosensor comprises a monitor photosensor.

10. The reflective optical encoder of claim 1 wherein at least one of the separate photosensor groupings comprises more than one photosensor.

11. An optical encoder comprising:
means for generating multiple light signals incident on a track of a coding element, wherein the track comprises coding sections; and
means for detecting motion of the coding element; and
means for reducing cross-talk of the multiple light signals.

12. The optical encoder of claim 11 further comprising means for encapsulating the optical encoder.

13. The optical encoder of claim 11 further comprising means for directing the light signals to the track, and for directing reflected light signals to the detecting means.

14. The optical encoder of claim 11 wherein the coding element comprises a reflective coding element.

15. The optical encoder of claim 11 wherein the coding element comprises an imaging coding element.

16. A detector within an optical encoder, the detector comprising:
a first photosensor grouping positioned near a first edge of the detector, wherein the first photosensor grouping comprises at least one photosensor; and
a second photosensor grouping positioned at an opposite edge of the detector, wherein the second photosensor grouping comprises at least one photo sensor.

17. The detector of claim 16 wherein the first and second photosensor groupings are positioned to align with first and second emitters.

18. The detector of claim 17 wherein the first and second photosensor groupings are positioned to align with first and second optical lenses.

19. The detector of claim 16 wherein the first and second photosensor groupings comprise different numbers of photosensors.

20. The detector of claim 16 wherein the coding element comprises a code wheel, wherein the first photosensor grouping is positioned along a first radial line of the code wheel at a first non-zero angle with respect to the first edge of the detector, and the second photosensor grouping is positioned along a second radial line of the code wheel at a second non-zero angle with respect to the opposite edge of the detector.
